(19) United States
(12) Patent Application Publication
(10) Pub. No.: US 2023/0418345 A1
(43) Pub. Date: Dec. 28, 2023

(54) DISPOSAL OF REFRIGERATION APPLIED IN MACHINES OR EQUIPMENT OR KITS FOR MINING CRYPTOCURRENCIES AND/OR FOR DATA PROCESSING

(71) Applicant: Jose Augusto Vullo, Buenos Aires (AR)

(72) Inventor: Jose Augusto Vullo, Buenos Aires (AR)

(21) Appl. No.: 18/064,966

(22) Filed: Dec. 13, 2022

(30) Foreign Application Priority Data
Jun. 22, 2022 (AR) M20220101634

(51) Int. Cl. G06F 1/20; H05K 7/20

(52) U.S. Cl. CPC G06F 1/20; H05K 7/20172

(57) ABSTRACT

A cooling arrangement applied in machines or equipment or kits to mine cryptocurrencies, designed to dissipate heat more efficiently through multiple fans locating the video cards (GPU) obliquely and transversely with respect to the mentioned multiple fans, with an angle between 15° and 75°.

### TECHNICAL FIELD OF THE INVENTION

This application refers to a “cooling arrangement applied in machines or equipment or kits for cryptocurrency mining^{o} that are susceptible to generate a great amount of heat during the working process and this heat is only dissipated by the fan exhaust unit, so the heat dissipation efficiency is low, so it does not result convenient to use.

### Technique State and Problems to be Solved

In the cryptocurrency mining process, the hardware is put at the service of a crypto-assets network such as Bitcoin, Ethereum, or any other type of cryptocurrency. What this hardware does is to confirm that the transactions, carried out on the network by its users, are valid.

It is known that a mining “rig” is a system based mainly on graphic cards that work to obtain the hash blockchain and thus obtain a reward. A mining rig has the same components as a conventional computer, but instead of one graphic card, it has several.

The number of graphic cards is limited by the design of the motherboard and the chassis where we mount the graphic cards.

Also, the machines or equipment or kits to mine cryptocurrencies, include video cards (GPU) of a similar format to parallelepipeds (rectangular in volume).

Currently, the world standard for assembling mining machines, places the GPUs in horizontal position and each one parallel to the other. They also use extra fans to cool the plates, which are arranged transversely to the GPUs (see FIG. 1).

The detected problem is that one of its sides shows high temperatures, so, on the opposite side, there are fans to cool the high temperature side.

On one of its lateral sides, the air blown by the fans and heated by the hot plate, is expelled.

### SUMMARY OF THE INVENTION

The suggested solution includes an optimization in heat dissipation, assembling the vector components of both hot air flows generated by the GPU, which are:
1) the air heated by the high temperature side of the GPU
2) the air flow generated by the fans and evacuated by the side.

To do this, the current architecture is modified and a particular arrangement is provided:
A) the GPUs are inclined obliquely between 15° and 75° degrees (sexagesimal) with respect to the fans, reflected in (FIG. 2), defined with representative longitudinal and perpendicular axes “X and Y”;
B) the fans are arranged perpendicularly to the traditional way.

### Technical Effect

No GPU fan will take hot air (as it currently happens) from the neighboring GPU, to be sent to the hot plate that it should cool.

ENERGY EFFICIENCY level: as the temperature drops, the GPUs consume less energy as well as the fans.

PERFORMANCE level: the equipment can carry out greater calculation capacity due to the effect of immediate heat extraction than in the conventional way

Equipment AMORTIZATION level: the lifespan is extended by not stressing the equipment at high temperatures.

COMMERCIAL level: having only one air flow direction, it allows the development of a home, industrial or any other kind of environment heating system.

With this new suggested arrangement, the inventor has obtained evidence that the equipment registered lower temperatures, lower energy consumption and greater mining power.

With this arrangement, the hot surface is more exposed to the fresh air flow emitted by the fans.

### BRIEF DESCRIPTION OF THE FIGURES

FIG. 1 illustrates a conventional mining machine or equipment or kits corresponding to the prior architecture where the GPUs (video card) are arranged horizontally and parallel and equidistant from each other.

FIG. 2A illustrates a perspective front view of a mining machine or equipment or kits according to the objective of the invention;

FIG. 2B illustrates a rear view of the mining machine of FIG. 2A;

FIG. 3A illustrates a top view of the mining machine of FIG. 2A showing the constitutive elements and the air circulation system (wind channels) for the GPUs (video cards) cooling; and

FIG. 3B illustrates a detailed view of the constitutive elements and the air circulation system (wind channels) for the GPUs (video cards) cooling.

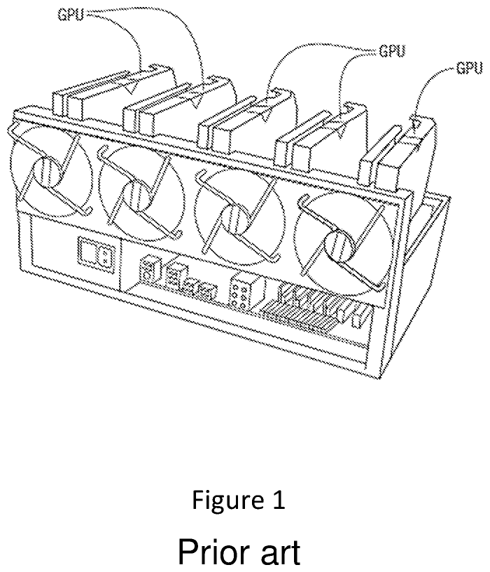

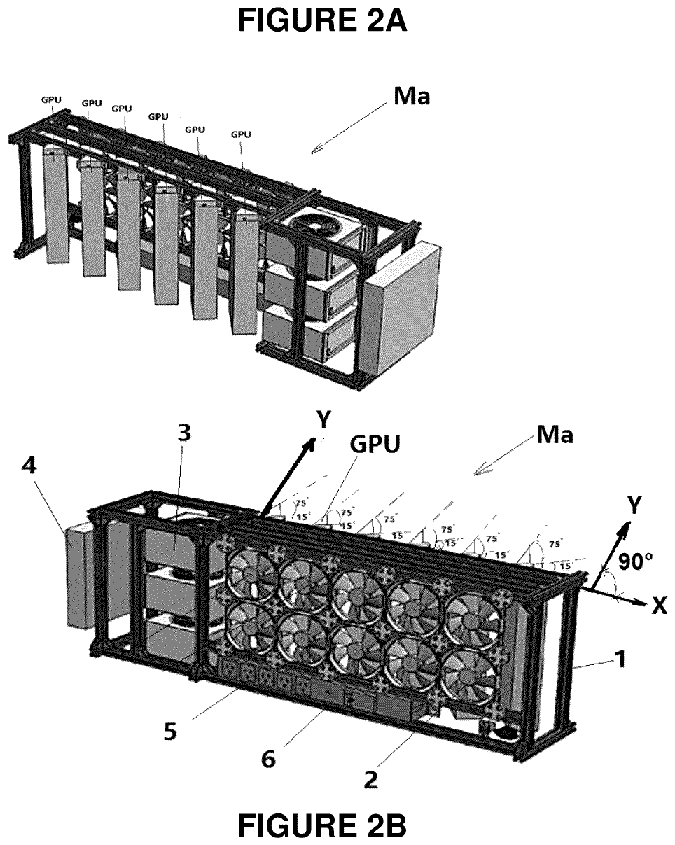

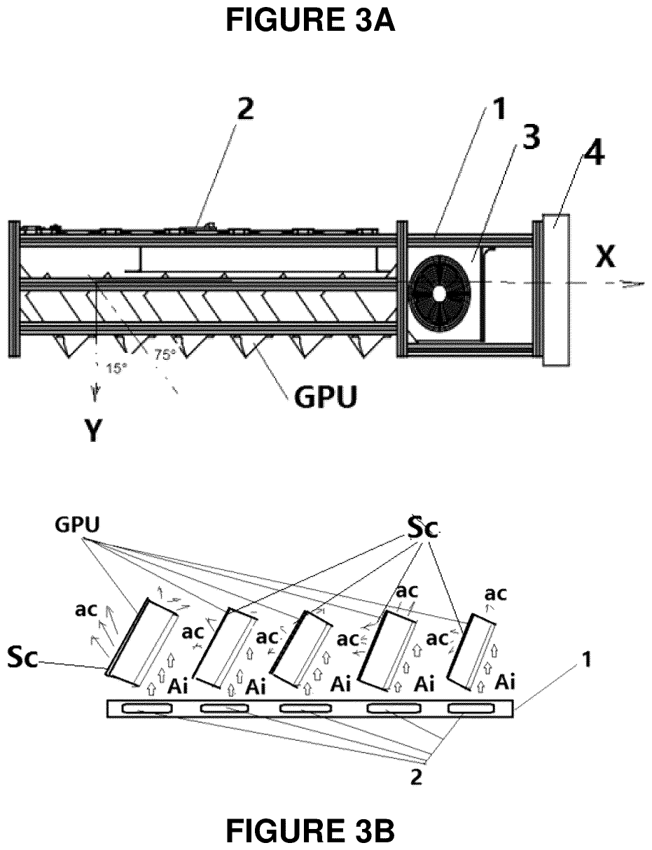

### DESCRIPTION

The involved components in the representative figures are:
Ma: Machine or equipment or mining kits.
GPU: Video cards.
Ai: Insufflated air.
ac: Hot air. (Heat dissipation).
Sc: Hot surface.
1—Structural frame chassis.
2—Fans.
3—Power sources.
4—Drive motor.
5—Electrical outlet.
6—Microprocessor.

Therefore, in the conventional case, it only impacts on the side of the smaller face of the GPUs, showing less heat dissipation and high temperature.

The suggested design has a basic operating principle, in which, when activating the machine or equipment or kits the multiple fans rotate emitting an air flow forming wind channels directed to the video cards or GPUs, being in an oblique direction and, with that inclination, the airflow impacts on the largest face of the GPUs where the temperature is the highest, showing optimal cooling and efficient heat dissipation, etc.

Having described and specified the nature of the invention and the way to put it into practice, we declare it to be claimed as a right and property.

1. A cooling arrangement applied in machines or equipment or kits to mine cryptocurrencies containing: a structural frame chassis (1) to support video cards (GPU) with a similar to parallelepipeds format (rectangular in volume) parallel and equidistant from each other; multiple extra fans (3) to cool the video cards (GPU); a drive motor (4) connected to power supplies (3); a plurality of electrical outlets (5); and a microprocessor (6); the video cards (GPU) are arranged obliquely and transversely with respect to the multiple fans (3) and with an angle between 15° and 75°.
